(19) United States
(12) Patent Application Publication
(10) Pub. No.: US 2015/0202555 A1
(43) Pub. Date: Jul. 23, 2015

(54) METHOD AND APPARATUS FOR CONDITIONING PROCESS LIQUIDS

(71) Applicant: LAM RESEARCH AG, Villach (AT)

(72) Inventor: Thomas KOMETTER, Villach/Carinthia (AT)

(73) Assignee: LAM RESEARCH AG, Villach (AT)

(21) Appl. No.: 14/158,425

(22) Filed: Jan. 17, 2014

(51) Int. Cl. B01D 35/26; H01L 21/67; C23F 1/08; C23F 1/46; B01D 35/18; B08B 3/14

(52) U.S. Cl. CPC B01D 35/26; B01D 35/18; B08B 3/14; C23F 1/08; C23F 1/46; H01L 21/67075; H01L 21/67051

(57) ABSTRACT

An apparatus for conditioning a process liquid comprises a tank incorporating a heat transfer device for heating or cooling a process liquid in the tank. A filtration unit is mounted within the tank for filtering the process liquid in the tank. A pump is mounted adjacent the tank and in fluid communication with process liquid in the tank. The pump causes process liquid to circulate between the filtration unit and the heat transfer device.

### BACKGROUND OF THE INVENTION

1. Field of the Invention

The invention relates to methods and apparatus for conditioning process liquids, especially in connection with equipment for processing semiconductor wafers, as well as to an apparatus for processing wafer-shaped articles that incorporates the conditioning apparatus.

2. Description of Related Art

Liquid treatment of semiconductor wafers includes both wet etching and wet cleaning, wherein the surface area of a wafer to be treated is wetted with a treatment liquid and a layer of the wafer is thereby removed or impurities are thereby carried off. Devices for such treatment may process multiple wafers in a batchwise manner, or may treat individual wafers, commonly using a spin chuck for example as described in U.S. Pat. No. 4,903,717.

Regardless of the processing equipment, it is required to supply process liquids that have been properly conditioned as regards their temperature and level of particulate contaminants. Such liquids may for example be strong inorganic acids, mixtures of strong inorganic acids and strong oxidizing agents, either in liquid form or as a foam-like mixed gas-liquid phase, as well as rinsing and drying agents such as deionized water and isopropyl alcohol, and mixtures thereof.

In conventional apparatus, the equipment for heating or cooling the process liquid, the filtration unit(s) and the supply pump are provided as separate units interconnected by appropriated conduits, valves and fittings. However, such systems are inefficient in terms of their space requirements, and involve a tremendous amount of work to establish and maintain all of the necessary interconnecting conduits and associated fittings.

### SUMMARY OF THE INVENTION

Thus, in one aspect, the present invention relates to an apparatus for conditioning a process liquid, that comprises a tank incorporating a heat transfer device for heating or cooling a process liquid in the tank. A filtration unit is mounted within the tank for filtering the process liquid in the tank. A pump is mounted adjacent the tank and in fluid communication with process liquid in the tank. The pump causes process liquid to circulate between the filtration unit and the heat transfer device.

In preferred embodiments of the conditioning apparatus according to the present invention, the heat transfer device comprises heat exchange tubing surrounding the filtration unit.

In preferred embodiments of the conditioning apparatus according to the present invention, the pump draws process liquid from an inlet into the tank through an interior of the filtration unit and into the pump via an opening formed in a wall of the tank, and impels process liquid into a filtering inlet of the filtering unit.

In preferred embodiments of the conditioning apparatus according to the present invention, the pump comprises a flange mounted to a wall of the tank, the flange comprising an inlet to the pump aligned with a first opening in the wall, and an outlet from the pump aligned with one or more second openings in the wall.

In preferred embodiments of the conditioning apparatus according to the present invention, the first opening in the wall is aligned with a passage through the filtration unit, and the one or more second openings in the wall are aligned with an inlet region of the filtration unit.

In preferred embodiments of the conditioning apparatus according to the present invention, the heat transfer device comprises a coil that coaxially surrounds an exterior of the filtration unit.

In preferred embodiments of the conditioning apparatus according to the present invention, an outlet of the filtration unit is joined to an outlet conduit that leads filtered and temperature-adjusted process liquid out of the tank without again contacting the heat transfer device.

In preferred embodiments of the conditioning apparatus according to the present invention, the filtration unit comprises a tube-shaped filter medium, an inlet region of the filtering unit is positioned radially outwardly of the tube-shaped filter medium, and an outlet of the filtration unit is positioned radially inwardly of the tube-shaped filter medium.

In preferred embodiments of the conditioning apparatus according to the present invention, the filtration unit comprises a central passageway traversing and bypassing the filtration unit, the passageway opening into the tank at one end and adjoining an opening in a wall of the tank at another end.

In preferred embodiments of the conditioning apparatus according to the present invention, the opening in the wall of the tank leads to an inlet of the pump.

In preferred embodiments of the conditioning apparatus according to the present invention, the process liquid is an acid or base for treating semiconductor surfaces.

In another aspect, the present invention relates to a method for conditioning a process liquid, comprising introducing process liquid into a tank and into contact with a heat transfer device disposed within the tank for heating or cooling the process liquid. The process liquid is drawn out of the tank by operation of a pump mounted adjacent to the tank. The process liquid is then impelled into a filtration unit that is mounted within the tank.

In preferred embodiments of the method according to the present invention, process liquid is drawn into the pump through a passageway in the filtration unit that traverses and bypasses the filtration unit.

In preferred embodiments of the method according to the present invention, conditioned process liquid is expelled from the tank by leading conditioned process liquid into a conduit that connects an outlet of the filtration unit with an outlet of the tank.

In yet another aspect, the present invention relates to an apparatus for processing wafer-shaped articles, comprising a holder for holding a wafer-shaped article during processing. A liquid dispenser is positioned relative to the holder so as to dispense a process liquid onto a wafer-shaped article when positioned on the holder. An apparatus for conditioning a process liquid is connected to an inlet of said liquid dispensing device. The conditioning apparatus comprises a tank incorporating a heat transfer device for heating or cooling a process liquid in the tank. A filtration unit is mounted within the tank for filtering the process liquid in the tank. A pump is mounted adjacent the tank and in fluid communication with process liquid in the tank. The pump causes process liquid to circulate between the filtration unit and the heat transfer device.

In preferred embodiments of the processing apparatus according to the present invention, the holder is a spin chuck.

In preferred embodiments of the conditioning apparatus according to the present invention, the holder is positioned in a process module for single wafer wet processing of semiconductor wafers.

In preferred embodiments of the conditioning apparatus according to the present invention, the conditioning apparatus is configured as a modular assembly comprising the tank, the heat transfer device, the filtration unit and the pump.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is a schematic view of a wafer-processing apparatus including the conditioning apparatus according to the present invention;

FIG. 2 is a perspective view, partially broken away, of a preferred embodiment of a conditioning apparatus according to the present invention; and

FIG. 3 shows the apparatus of FIG. 2 in section so as to illustrate its operation.

### DETAILED DESCRIPTION OF PREFERRED EMBODIMENTS

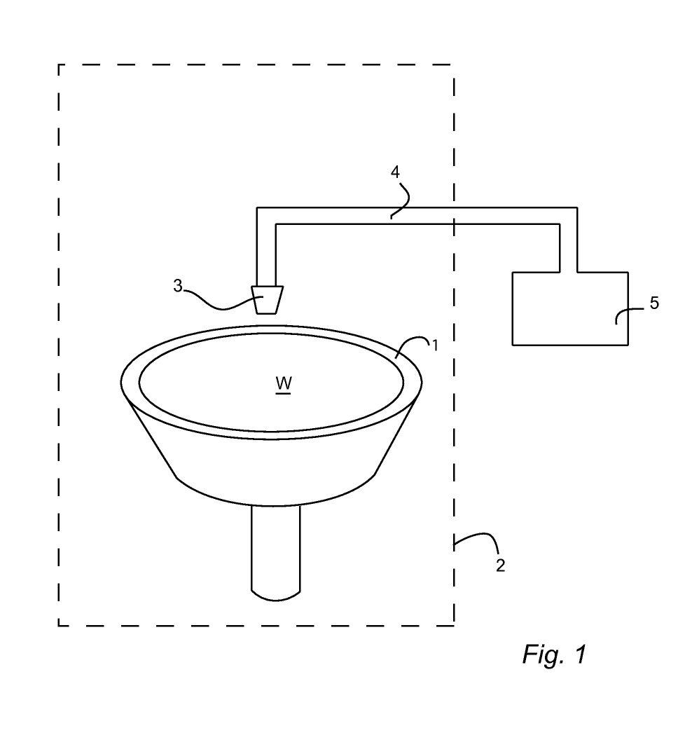

Referring now to the drawings, FIG. 1 schematically illustrates a spin chuck 1 holding a wafer W. Spin chuck 1 in this embodiment is present within a process module 2 for single wafer wet processing of semiconductor wafers. Process module 2 typically includes several spin chucks 1. Each spin chuck includes a liquid dispenser having an outlet nozzle 3 which can be positioned as shown in FIG. 1 so as to dispense process liquid onto wafer W.

Liquid dispenser 2 is supplied via conduit 4 by an apparatus for conditioning process liquid 5 to be described in detail hereinafter. The conditioning apparatus 5 in this embodiment is positioned outside the process module 5 and thus may supply plural process modules. Alternatively, the conditioning apparatus 5 may be positioned within the process module 2 and supply only the spin chuck(s) 1 within that process module 2.

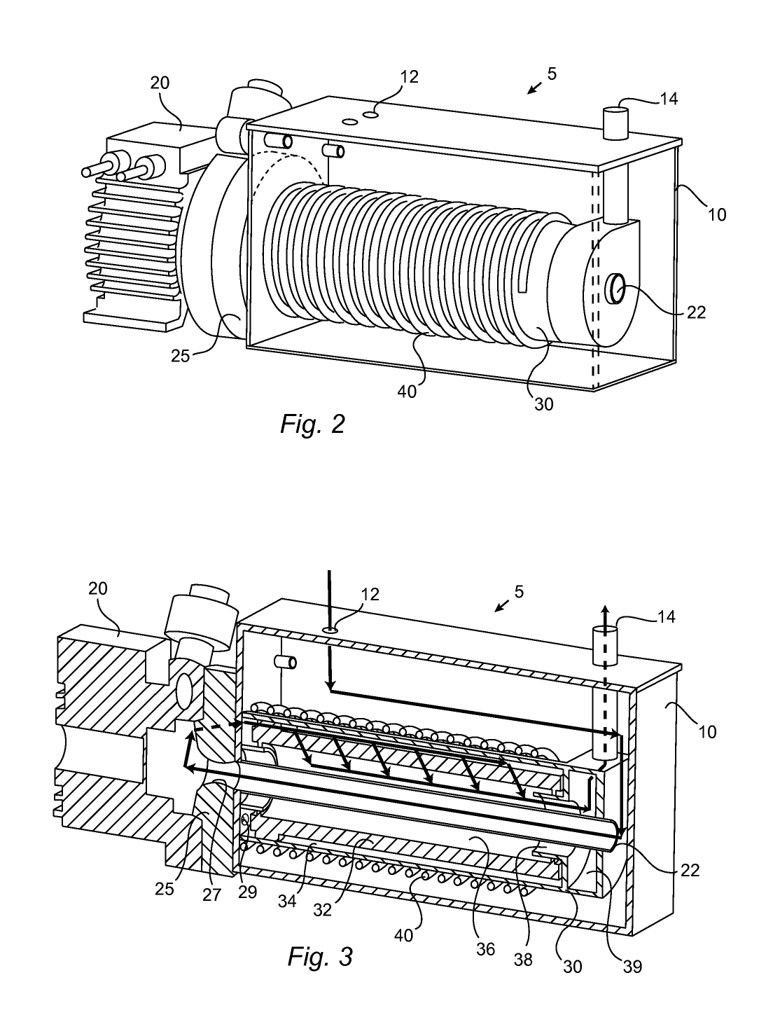

FIG. 2 shows the construction of a conditioning apparatus 5 according to a preferred embodiment. Apparatus 5 is formed as a single modular assembly comprising a tank 10 that incorporates both a filtration unit 30 and a heat exchange device 40. A pump 20 is mounted to one end of tank 10 via a specially-designed flange interface 25.

Heat exchange device 40 may be a heating element, for example, an electrical resistance coil, for heating a process liquid in the tank 10. Alternatively, heat exchange device may be a helical conduit carrying a heat-exchange fluid, such as a suitable refrigerant where it is desired to lower the temperature of the process liquid.

As shown in FIG. 3, the pump 20 has a central inlet and a peripheral outlet. In operation, when the pump is running liquid can be drawn into the tank 10 through inlet 12. Alternatively, the tank 10 may be previously filled with process liquid. The heat exchange device 40 is operated when the tank 10 is at least partly filled with process liquid, and it may be operated either in a steady state continuous mode simultaneously with the pump 20 or in a batch mode while the pump 20 is switched off.

Process liquid in tank 10 contacts the heat exchange device 40 upon entering the tank 10, and before it is drawn into the pump 20. As the process liquid continues toward the pump 20, it first enters the open distal end of a conduit 22 that is in this embodiment arranged coaxially with the filtration unit 30 and the heat exchange unit 40. Conduit 22 runs through the filtration unit 30 and also bypasses the filter medium 32 of the filtration unit.

The process liquid then is drawn into the pump 20, through the central inlet 27 formed in mounting flange 25. The continued operation of pump 20 then causes the process liquid to be expelled through one or more peripheral outlets 29 of the pump 20 and flange 25, which discharge the process liquid into the peripheral inlet region 34 of the filtration unit 30. This inlet region 34 is the annular volume within the filtration unit and radially outside the cylindrical filter medium 32.

Further heating or cooling of the process liquid may occur if desired within the inlet region 34 of the filtration unit 30, by making the outer cylindrical wall of filtration unit 30 of a thermally conductive material. The process liquid is filtered as it passes radially inwardly from inlet region 34 to the central region 36, passing through the filter medium 32.

From the central region 36, the temperature-adjusted and filtered process liquid then flows through an outlet 38 of the filtration unit 30, into an outlet manifold 39 that communicates with one or more outlet conduits 14. Each outlet conduit 14 supplies a respective liquid dispenser, as described in connection with FIG. 1.

It will be appreciated that the modular process liquid conditioning apparatus as described herein is substantially more space efficient than convention systems composed of multiple separate modules for heating, filtering and pumping; and moreover eliminates the need for a complicated network of conduits and fittings that are needed to interconnect the multiple separate modules used conventionally.

While the present invention has been described in connection with various preferred embodiments thereof, it is to be understood that those embodiments are provided merely to illustrate the invention, and should not be used as a pretext to limit the scope of protection conferred by the true scope and spirit of the appended claims.

What is claimed is:

1. Apparatus for conditioning a process liquid, comprising:
a tank comprising a heat transfer device for heating or cooling a process liquid in said tank;
a filtration unit mounted within said tank for filtering the process liquid in the tank; and
a pump mounted adjacent the tank and in fluid communication with process liquid in the tank, the pump causing process liquid to circulate between the filtration unit and the heat transfer device.

2. The apparatus according to claim 2, wherein said heat transfer device comprises heat exchange tubing surrounding said filtration unit.

3. The apparatus according to claim 1, wherein said pump draws process liquid from an inlet into said tank through an interior of said filtration unit and into said pump via an opening formed in a wall of said tank, and impels process liquid into a filtering inlet of said filtering unit.

4. The apparatus according to claim 1, wherein said pump comprises a flange mounted to a wall of said tank, said flange comprising an inlet to said pump aligned with a first opening in said wall, and an outlet from said pump aligned with one or more second openings in said wall.

5. The apparatus according to claim 4, wherein said first opening in said wall is aligned with a passage through said filtration unit, and said one or more second openings in said wall are aligned with an inlet region of said filtration unit.

6. The apparatus according to claim 1, wherein said heat transfer device comprises a coil that coaxially surrounds an exterior of said filtration unit.

7. The apparatus according to claim 1, wherein an outlet of said filtration unit is joined to an outlet conduit that leads filtered and temperature-adjusted process liquid out of said tank without again contacting said heat transfer device.

8. The apparatus according to claim 1, wherein said filtration unit comprises a tube-shaped filter medium, and wherein an inlet region of said filtering unit is positioned radially outwardly of said tube-shaped filter medium, and an outlet of said filtration unit is positioned radially inwardly of said tube-shaped filter medium.

9. The apparatus according to claim 1, wherein said filtration unit comprises a central passageway traversing and bypassing the filtration unit, said passageway opening into said tank at one end and adjoining an opening in a wall of said tank at another end.

10. The apparatus according to claim 9, wherein said opening in the wall of said tank leads to an inlet of said pump.

11. The apparatus according to claim 1, wherein the process liquid is an acid or base for treating semiconductor surfaces.

12. Method for conditioning a process liquid, comprising:
introducing process liquid into a tank and into contact with a heat transfer device disposed within the tank for heating or cooling the process liquid;
drawing process liquid out of said tank by operation of a pump mounted adjacent to said tank; and
impelling process liquid into a filtration unit that is mounted within said tank.

13. The method according to claim 12, wherein process liquid is drawn into said pump through a passageway in said filtration unit that traverses and bypasses the filtration unit.

14. The method according to claim 12, further comprising expelling conditioned process liquid from said tank by leading conditioned process liquid into a conduit that connects an outlet of said filtration unit with an outlet of said tank.

15. Apparatus for processing wafer-shaped articles, comprising:
a holder for holding a wafer-shaped article during processing;
a liquid dispenser positioned relative to said holder so as to dispense a process liquid onto a wafer-shaped article when positioned on the holder; and
an apparatus for conditioning a process liquid, said apparatus comprising:
a tank comprising a heat transfer device for heating or cooling a process liquid in said tank;
a filtration unit mounted within said tank for filtering the process liquid in the tank; and
a pump mounted adjacent the tank and in fluid communication with process liquid in the tank, the pump causing process liquid to circulate between the filtration unit and the heat transfer device;
wherein an outlet of said conditioning apparatus is connected to an inlet of said liquid dispenser.

16. The apparatus according to claim 15, wherein said holder is a spin chuck.

17. The apparatus according to claim 15, wherein said holder is positioned in a process module for single wafer wet processing of semiconductor wafers.

18. The apparatus according to claim 15, wherein said conditioning apparatus is configured as a modular assembly comprising said tank, said heat transfer device, said filtration unit and said pump.
